(19) United States
(12) Patent Application Publication
(10) Pub. No.: US 2025/0156599 A1
(43) Pub. Date: May 15, 2025

(54) DETECTION OF EMERGING HERBICIDE RESISTANCE IN WEED POPULATIONS

(71) Applicant: Geco Strategic Weed Management Inc., North Vancouver (CA)

(72) Inventor: Gregory E. Stewart, North Vancouver (CA)

(21) Appl. No.: 18/726,074

(22) PCT Filed: Dec. 22, 2022
(86) PCT No.: PCT/IB2022/062710

§ 371 Date: Jul. 1, 2024

Related U.S. Application Data
(60) Provisional application No. 63/296,706, filed on Jan. 5, 2022.

(51) Int. Cl. G06F 30/20

(52) U.S. Cl. CPC G06F 30/20

(57) ABSTRACT

A method includes obtaining, using at least one processing device (202, 314) of an electronic device (102a-102d, 106, 200, 300), spatial information (500, 600, 800, 900, 1100, 1200) associated with weeds in a growing area. The spatial information includes spatial information (500, 800, 1100) associated with a primary weed in the growing area over time. The method also includes identifying, using the at least one processing device, one or more portions of the growing area in which the primary weed has developed or may be developing herbicide resistance using the spatial information. In addition, the method includes outputting, using the at least one processing device, information (700, 1000, 1300) associated with the one or more identified portions of the growing area.

### CROSS-REFERENCE TO RELATED APPLICATION AND PRIORITY CLAIM

This application claims priority to U.S. Provisional Patent Application No. 63/296,706 filed on Jan. 5, 2022. This provisional application is hereby incorporated by reference in its entirety.

### TECHNICAL FIELD

This disclosure is generally directed to detection systems. More specifically, this disclosure is directed to the detection of emerging herbicide resistance in weed populations.

### BACKGROUND

Herbicides are a primary tool for the control of weeds in modern agricultural production, providing a way to achieve optimum crop yields and enabling the adoption of environmentally-friendly practices such as conservation tillage. In most of the world's major crop production areas, the evolution of weed populations with resistance to one or more herbicides is a serious concern. Herbicide resistance is defined as the acquired ability of a weed population to survive an herbicide application that previously was known to control the weed population. Herbicide resistance is a natural response of populations of certain weed species to the use of herbicides and can be mitigated using recognized best management practices.

### SUMMARY

This disclosure relates to the detection of emerging herbicide resistance in weed populations.

In a first embodiment, a method includes obtaining, using at least one processing device of an electronic device, spatial information associated with weeds in a growing area. The spatial information includes spatial information associated with a primary weed in the growing area over time. The method also includes identifying, using the at least one processing device, one or more portions of the growing area in which the primary weed has developed or may be developing herbicide resistance using the spatial information. In addition, the method includes outputting, using the at least one processing device, information associated with the one or more identified portions of the growing area.

In a second embodiment, an apparatus includes at least one processing device configured to obtain spatial information associated with weeds in a growing area. The spatial information includes spatial information associated with a primary weed in the growing area over time. The at least one processing device is also configured to identify one or more portions of the growing area in which the primary weed has developed or may be developing herbicide resistance using the spatial information. The at least one processing device is further configured to output information associated with the one or more identified portions of the growing area.

In a third embodiment, a non-transitory computer readable medium stores computer readable program code that, when executed by one or more processors, causes the one or more processors to obtain spatial information associated with weeds in a growing area. The spatial information includes spatial information associated with a primary weed in the growing area over time. The non-transitory computer readable medium also stores computer readable program code that, when executed by the one or more processors, causes the one or more processors to identify one or more portions of the growing area in which the primary weed has developed or may be developing herbicide resistance using the spatial information. The non-transitory computer readable medium further stores computer readable program code that, when executed by the one or more processors, causes the one or more processors to output information associated with the one or more identified portions of the growing area.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIG. 1 illustrates an example system supporting the detection of emerging herbicide resistance in weed populations according to this disclosure;

FIG. 2 illustrates an example computing device supporting the detection of emerging herbicide resistance in weed populations according to this disclosure;

FIG. 3 illustrates an example user device that may be used to support the detection of emerging herbicide resistance in weed populations according to this disclosure;

FIG. 4 illustrates an example method for detection of emerging herbicide resistance in weed populations according to this disclosure;

FIGS. 5 through 7 illustrate a first example detection of emerging herbicide resistance in weed populations according to this disclosure;

FIGS. 8 through 10 illustrate a second example detection of emerging herbicide resistance in weed populations according to this disclosure; and

FIGS. 11 through 13 illustrate a third example detection of emerging herbicide resistance in weed populations according to this disclosure.

### DETAILED DESCRIPTION

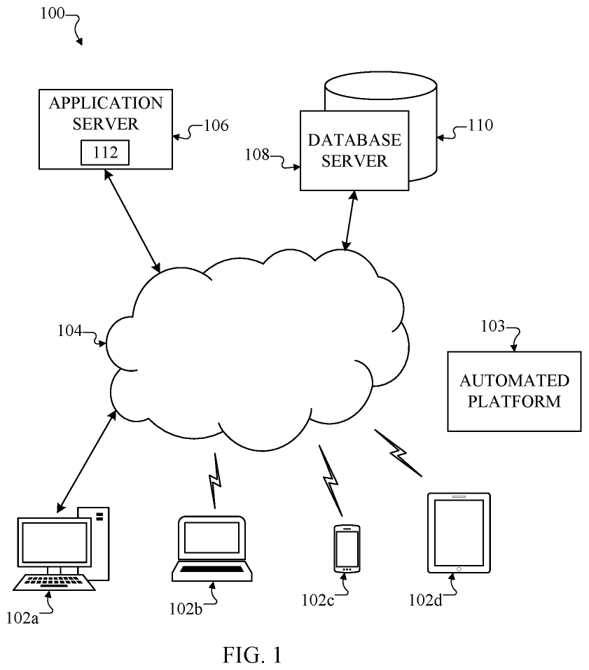

FIGS. 1 through 13, described below, and the various embodiments used to describe the principles of the present invention in this patent document are by way of illustration only and should not be construed in any way to limit the scope of the invention. Those skilled in the art will understand that the principles of the present invention may be implemented in any type of suitably arranged device or system.

As noted above, herbicides are a primary tool for the control of weeds in modern agricultural production, providing a way to achieve optimum crop yields and enabling the adoption of environmentally-friendly practices such as conservation tillage. In most of the world's major crop production areas, the evolution of weed populations with resistance to one or more herbicides is a serious concern. Herbicide resistance is defined as the acquired ability of a weed population to survive an herbicide application that previously was known to control the weed population. Herbicide resistance is a natural response of populations of certain weed species to the use of herbicides and can be mitigated using recognized best management practices.

Unfortunately, standard techniques for identifying herbicide resistance in weeds can suffer from various shortcomings. For example, collecting and testing seeds from potentially herbicide resistant weeds is labor-intensive and is often better applied on a regional basis rather than for specific growing areas, and these activities are often not sustained over time due to the effort involved. Market research surveys of farmers and weed management experts are known to be unreliable, especially for new cases of herbicide resistance in a region. In addition, tracking farmer performance inquiries with appropriate follow-up field evaluation and testing, while very reliable to detect herbicide resistance, often allows large percentages of weeds in a growing area to become herbicide resistant prior to detection.

This disclosure describes various techniques supporting the detection of emerging herbicide resistance in weed populations. For example, spatial distributions of one or more weeds (often called weed maps) in at least one farm field or other growing area can be obtained in any suitable manner. In some cases, weed maps may be generated by people performing manual scouting of the growing area(s). In other cases, weed maps may be generated by automated systems that can detect weeds in the growing area(s). As a particular example, weed maps may be generated by a “see-and-spray” automated system that uses computer vision to detect weeds and to control an herbicide sprayer to spray the weeds (ideally while minimizing spraying of other areas). As other particular examples, a computer vision system may be mounted on a tractor, an airborne propeller or fixed wing drone, an airplane, a satellite, or other suitable device. However the weed maps are generated, the weed maps can be analyzed in order to identify one or more patches of the growing area(s) that may contain weeds that have become or may be becoming herbicide resistant.

Various types of analyses of the weed maps may occur here in order to identify weeds that have become or may be becoming herbicide resistant. For example, weed maps for a specific weed (referred to as a primary weed) can be obtained over time, such as after multiple spray events or during multiple growing seasons (like multiple years). The weed maps can be analyzed in order to determine if the primary weed has survived at least one herbicide application and appears to have expanded in one or more patches of a growing area over time, which can be indicative of herbicide resistance. It is also possible to use one or more weed maps of other weeds (referred to as secondary weeds) to determine whether expansion of the primary weed is due to herbicide resistance or some other factors (such as improper application of an herbicide). For instance, when an expanding patch of a primary weed is identified, a determination can be made whether the one or more secondary weeds are also present at a higher rate in that patch (which can be determined using collected data or by manually inspecting the patch). If so, this may be indicative of improper herbicide application or other non-herbicide resistance problem since it is unlikely multiple types of weeds will simultaneously develop herbicide resistance (at least at the same rate). Otherwise, this may be indicative of herbicide resistance since the herbicide appears to be working effectively for the one or more secondary weeds.

FIG. 1 illustrates an example system 100 supporting the detection of emerging herbicide resistance in weed populations according to this disclosure. As shown in FIG. 1, the system 100 includes user devices 102a-102d, one or more automated platforms 103, one or more networks 104, one or more application servers 106, and one or more database servers 108 associated with one or more databases 110. Each user device 102a-102d communicates over the network 104, such as via a wired or wireless connection. Each user device 102a-102d represents any suitable device or system used by at least one user to provide or receive information, such as a desktop computer, a laptop computer, a smartphone, and a tablet computer. However, any other or additional types of user devices may be used in the system 100. In some cases, one or more users may use one or more user devices 102a-102d to identify weeds in at least one growing area. In other cases, one or more users may use one or more user devices 102a-102d to view a graphical user interface or other interface that presents analysis results, such as an identification of any patches in a growing area associated with herbicide resistance.

Each automated platform 103 represents a device or system that is configured to identify weeds (and possibly types of weeds) in one or more growing areas. For example, as noted above, an automated platform 103 may represent a “see-and-spray” system that locates weeds and sprays the weeds with an herbicide. In some cases, the “see-and-spray” system uses computer vision to detect weeds and to control an herbicide sprayer to spray the weeds (ideally while minimizing spraying of other areas). As another example, a computer vision system may be mounted on a tractor, an airborne propeller or fixed wing drone, an airplane, a satellite, or other suitable device. Each automated platform 103 includes any suitable structure for identifying weeds in at least one growing area.

The network 104 facilitates communication between various components of the system 100. For example, the network 104 may communicate Internet Protocol (IP) packets, frame relay frames, Asynchronous Transfer Mode (ATM) cells, or other suitable information between network addresses. The network 104 may include one or more local area networks (LANs), metropolitan area networks (MANs), wide area networks (WANs), all or a portion of a global network such as the Internet, or any other communication system or systems at one or more locations.

The application server 106 is coupled to the network 104 and is coupled to or otherwise communicates with the database server 108. The application server 106 supports the analysis of weed maps or other information to detect emerging herbicide resistance in weed populations. Example analysis operations that may be performed by the application server 106 are described below. For example, the application server 106 may execute one or more applications 112 that use data from the database 110 to detect emerging herbicide resistance in weed populations. In some cases, the application 112 identifies spatial areas of weeds using a clustering algorithm, where points associated with weeds may be included in a cluster based on their distance. In other cases, the application 112 identifies spatial areas of weeds using an anomaly detection algorithm, where points associated with weeds may be identified as an anomaly (such as based on their growth or death rates). As a particular example, the application 112 may identify points or clusters showing evidence of herbicide resistance via exhibiting a different growth rate or death rate than surrounding weeds or average weeds in the growing area.

The database server 108 operates to store and facilitate retrieval of various information used, generated, or collected by the application server 106, the user devices 102a-102d, and/or the automated platform(s) 103 in the database 110. For example, the database server 108 may store various information related to weed maps or other information for different weeds detected in one or more growing areas. Note that the database server 108 may also be used within the application server 106 to store information, in which case the application server 106 itself may store the information used to detect emerging herbicide resistance in weed populations.

Although FIG. 1 illustrates one example of a system 100 supporting the detection of emerging herbicide resistance in weed populations, various changes may be made to FIG. 1. For example, various components shown in FIG. 1 may be combined, further subdivided, replicated, omitted, or rearranged and additional components may be added according to particular needs. Also, the system 100 may include any number of user devices 102a-102d, automated platforms 103, networks 104, application servers 106, database servers 108, and databases 110 (possibly including zero of one or more of these components). Further, these components may be located in any suitable locations and might be distributed over a large area. In addition, while FIG. 1 illustrates one example operational environment in which the detection of emerging herbicide resistance in weed populations may be used, this functionality may be used in any other suitable system. As a particular example, one or more applications 112 implementing the detection of emerging herbicide resistance may be executed by one or more user devices 102a-102d or other devices.

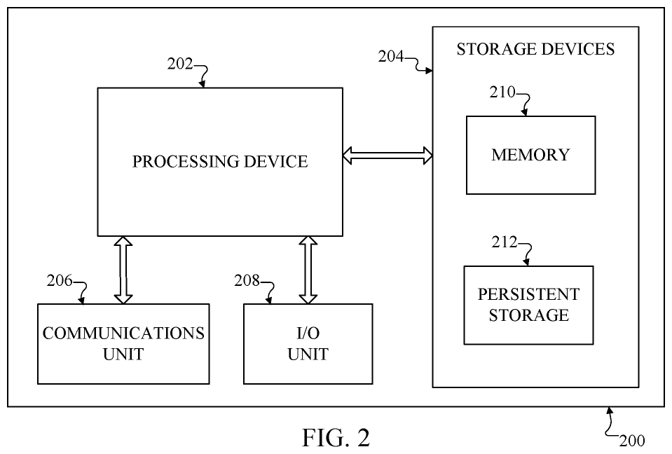

FIG. 2 illustrates an example computing device 200 supporting the detection of emerging herbicide resistance in weed populations according to this disclosure. One or more instances of the device 200 may, for example, be used to at least partially implement the functionality of the application server 106 of FIG. 1. However, the functionality of the application server 106 may be implemented in any other suitable manner. In some embodiments, the device 200 shown in FIG. 2 may form at least part of a user device 102a-102d, automated platform 103, application server 106, or database server 108 in FIG. 1. However, each of these components may be implemented in any other suitable manner.

As shown in FIG. 2, the device 200 denotes a computing device or system that includes at least one processing device 202, at least one storage device 204, at least one communications unit 206, and at least one input/output (I/O) unit 208. The processing device 202 may execute instructions that can be loaded into a memory 210. The processing device 202 includes any suitable number(s) and type(s) of processors or other processing devices in any suitable arrangement. Example types of processing devices 202 include one or more microprocessors, microcontrollers, digital signal processors (DSPs), application specific integrated circuits (ASICs), field programmable gate arrays (FPGAs), or discrete circuitry.

The memory 210 and a persistent storage 212 are examples of storage devices 204, which represent any structure(s) capable of storing and facilitating retrieval of information (such as data, program code, and/or other suitable information on a temporary or permanent basis). The memory 210 may represent a random access memory or any other suitable volatile or non-volatile storage device(s). The persistent storage 212 may contain one or more components or devices supporting longer-term storage of data, such as a read only memory, hard drive, Flash memory, or optical disc.

The communications unit 206 supports communications with other systems or devices. For example, the communications unit 206 can include a network interface card or a wireless transceiver facilitating communications over a wired or wireless network, such as the network 104. The communications unit 206 may support communications through any suitable physical or wireless communication link(s).

The I/O unit 208 allows for input and output of data. For example, the I/O unit 208 may provide a connection for user input through a keyboard, mouse, keypad, touchscreen, or other suitable input device. The I/O unit 208 may also send output to a display, printer, or other suitable output device. Note, however, that the I/O unit 208 may be omitted if the device 200 does not require local I/O, such as when the device 200 represents a server or other device that can be accessed remotely.

In some embodiments, the processing device 202 executes instructions to detect emerging herbicide resistance in weed populations. For example, the processing device 202 may execute instructions that cause the processing device 202 to analyze weed maps and identify any patches in one or more growing areas where emerging herbicide resistance in weed populations may exist. Example analysis operations that may be performed by the processing device 202 are provided below.

Although FIG. 2 illustrates one example of a device 200 supporting the detection of emerging herbicide resistance in weed populations, various changes may be made to FIG. 2. For example, various components shown in FIG. 2 may be combined, further subdivided, replicated, omitted, or rearranged and additional components may be added according to particular needs. Also, computing and communication devices and systems come in a wide variety of configurations, and FIG. 2 does not limit this disclosure to any particular computing or communication device or system.

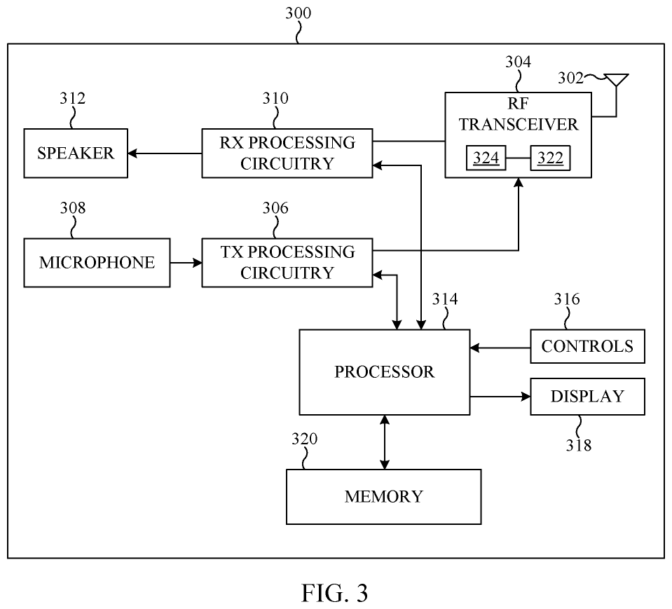

FIG. 3 illustrates an example user device 300 that may be used to support the detection of emerging herbicide resistance in weed populations according to this disclosure. One or more instances of the user device 300 may, for example, be used to at least partially implement the functionality of one or more of the user devices 102a-102d of FIG. 1. However, the functionality of the user devices 102a-102d may be implemented in any other suitable manner.

As shown in FIG. 3, the device 300 includes at least one antenna 302, at least one radio frequency (RF) transceiver 304, transmit (TX) processing circuitry 306, at least one microphone 308, receive (RX) processing circuitry 310, and at least one speaker 312. The device 300 also includes at least one processor 314, one or more physical controls 316, at least one display 318, and at least one memory 320. The antenna 302 is used to radiate outgoing RF electrical signals as wireless signals and to convert incoming wireless signals into RF electrical signals.

The RF transceiver 304 receives, from the antenna 302, the RF electrical signals representing incoming wireless signals, such as cellular, WiFi, BLUETOOTH, or navigation signals. The RF transceiver 304 down-converts the incoming RF signals to generate intermediate frequency (IF) or baseband signals. The IF or baseband signals are sent to the receive processing circuitry 310, which generates processed baseband signals by filtering, decoding, digitizing, and/or otherwise processing the baseband or IF signals. The receive processing circuitry 310 can transmit the processed baseband signals to the speaker 312 or to the processor 314 for further processing.

The transmit processing circuitry 306 receives analog or digital data from the microphone 308 or other outgoing baseband data from the processor 314. The transmit processing circuitry 306 encodes, multiplexes, digitizes, and/or otherwise processes the outgoing baseband data to generate processed baseband or IF signals. The RF transceiver 304 receives the outgoing processed baseband or IF signals from the transmit processing circuitry 306 and up-converts the baseband or IF signals to RF electrical signals that are transmitted via the antenna 302.

Each antenna 302 includes any suitable structure configured to transmit wireless signals and/or receive wireless signals. In some embodiments, an antenna 302 may represent a loop antenna. Also, in some embodiments, an antenna 302 may represent an antenna array having multiple antenna elements arranged in a desired pattern. Each transceiver 304 includes any suitable structure configured to generate outgoing RF signals for transmission and/or process incoming RF signals. Note that while shown as an integrated device, a transceiver 304 may be implemented using a transmitter and a separate receiver. The transmit processing circuitry 306 includes any suitable structure configured to encode, multiplex, digitize, or otherwise process data to generate signals containing the data. Each microphone 308 includes any suitable structure configured to capture audio signals. The receive processing circuitry 310 includes any suitable structure configured to filter, decode, digitize, or otherwise process signals to recover data from the signals. Each speaker 312 includes any suitable structure configured to generate audio signals. Note that if the device 300 only supports one-way communication, a transceiver 304 may be replaced with either a transmitter or a receiver, and either the transmit processing circuitry 306 or the receive processing circuitry 310 can be omitted.

The processor 314 include one or more processors or other processing devices and execute an operating system, applications, or other logic stored in the memory 320 in order to control the overall operation of the device 300. For example, the processor 314 can control the transmission, reception, and processing of signals by the RF transceiver 304, the receive processing circuitry 310, and the transmit processing circuitry 306 in accordance with well-known principles. The processor 314 is also configured to execute other processes and applications resident in the memory 320, and the processor 314 can move data into or out of the memory 320 as required by an executing application. The processor 314 includes any suitable processing device or devices, such as one or more microprocessors, microcontrollers, DSPs, ASICs, FPGAs, or discrete circuitry.

The processor 314 is coupled to the physical controls 316 and the display 318. A user of the device 300 can use the physical controls 316 to invoke certain functions, such as powering on or powering off the device 300 or controlling a volume of the device 300. The display 318 may be a liquid crystal display (LCD), light emitting diode (LED) display, organic light emitting diode (OLED) display, quantum light emitting diode (QLED) display, or other display configured to render text and graphics. If the display 318 denotes a touchscreen configured to receive touch input, fewer or no physical controls 316 may be needed in the device 300.

The memory 320 is coupled to the processor 314. The memory 320 stores instructions and data used, generated, or collected by the processor 314 or by the device 300. In some embodiments, part of the memory 320 can include a random access memory, and another part of the memory 320 can include a Flash memory or other read only memory. Each memory 320 includes any suitable volatile or non-volatile structure configured to store and facilitate retrieval of information.

In some embodiments, the processor 314 executes instructions to display analysis results related to any detected emerging herbicide resistance in weed populations. For example, the processor 314 may execute instructions that cause the processor 314 to present a graphical user interface on the display 318, where the graphical user interface identifies any patches in one or more growing areas where emerging herbicide resistance in weed populations may exist. Example interfaces that may be generated by the processor 314 are provided below.

Although FIG. 3 illustrates one example of a user device 300 that may be used to support the detection of emerging herbicide resistance in weed populations, various changes may be made to FIG. 3. For example, various components shown in FIG. 3 may be combined, further subdivided, replicated, omitted, or rearranged and additional components may be added according to particular needs. As a particular example, the processor 314 may be divided into multiple processors, such as one or more central processing units (CPUs) and one or more graphics processing units (GPUs). As another example, components such as the microphone 308 and speaker 312 may not be needed, depending on the type of device being used. In addition, mobile devices and other computing or communication devices come in a wide variety of configurations, and FIG. 3 does not limit this disclosure to any particular mobile device or other computing or communication device.

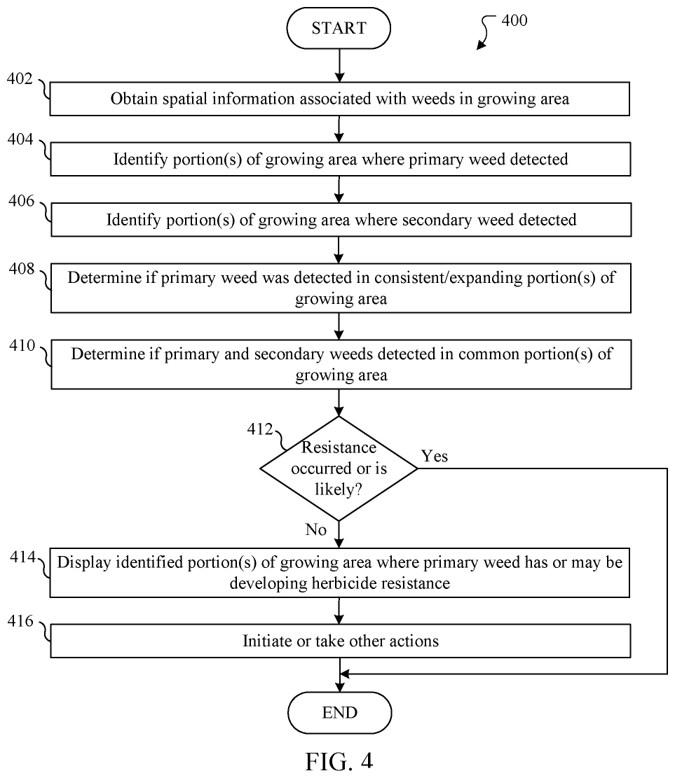

FIG. 4 illustrates an example method 400 for detection of emerging herbicide resistance in weed populations according to this disclosure. For ease of explanation, the method 400 is described as being performed by the application server 106 in the system 100 of FIG. 1, where the application server 106 may be implemented using one or more devices 200 of FIG. 2. However, the method 400 may be performed using any other suitable device(s) and in any other suitable system(s).

As shown in FIG. 4, spatial information associated with weeds in at least one growing area is obtained at step 402. This may include, for example, the processing device 202 of the application server 106 generating, receiving, or otherwise obtaining one or more weed maps. Each weed map may identify the location(s) of one or more weeds in a growing area. In some cases, different weed maps may be associated with different weeds or different types of weeds. The weed maps may be obtained from any suitable source(s), such as one or more user devices 102a-102d, one or more automated platforms 103, or other source(s). In some cases, information about locations of weeds may be obtained (such as from one or more user devices 102a-102d or one or more automated platforms 103), and the application server 106 may generate the weed maps. Also, in some cases, at least some of the weed maps can cover an extended period of time, at least for a primary weed. While longer periods of time may be beneficial, the weed maps associated with the primary weed may ideally cover at least two growing seasons. One or more weed maps for at least one secondary weed may only need to cover the current growing season, although nothing prevents usage of weed maps for at least one secondary weed that cover multiple growing seasons.

One or more portions of the at least one growing area in which a primary weed was detected can be identified at step 404, and one or more portions of the at least one growing area in which at least one secondary weed was detected can be identified at step 406. This may include, for example, the processing device 202 of the application server 106 analyzing the one or more weed maps to identify locations in the growing area(s) where primary and secondary weeds have been detected. In some embodiments, part of this process can involve the use of a clustering algorithm, which can identify spatial areas associated with clusters of primary and secondary weeds. For instance, the clustering algorithm may identify each spatial area as a cluster of primary or secondary weeds, where points in the growing area are included in the cluster based on their distance from one another (and optionally their distance from points associated with other weeds).

In this example, herbicide resistance can be identified based on various factors, such as the presence of the primary weed in consistent or expanding locations and/or the co-location or lack thereof with respect to the primary and secondary weeds. As a result, a determination is made whether the primary weed was detected in one or more consistent or expanding portions of the one or more growing areas at step 408. This may include, for example, the processing device 202 of the application server 106 identifying whether one or more spatial areas associated with the primary weed are at or near the same location(s) in a growing area from one growing season to the next. This may also include the processing device 202 of the application server 106 identifying whether one or more spatial areas associated with the primary weed overlap and are getting larger from one growing season to the next. A determination is made whether the primary and secondary weeds were detected in common portions of the one or more growing areas at step 410. This may include, for example, the processing device 202 of the application server 106 identifying whether one or more spatial areas associated with the primary weed do or do not overlap with one or more spatial areas associated with the secondary weed(s).

A determination is made whether herbicide resistance has occurred or is likely to occur at step 412. This may include, for example, the processing device 202 of the application server 106 determining whether the primary weed has been detected in consistent or expanding locations in the growing area(s). The presence of the primary weed in consistent or expanding locations can indicate that the primary weed is resistant or is becoming resistant to an herbicide used at those locations. This may also or alternatively include the processing device 202 of the application server 106 determining whether the primary weed is located in one or more locations where the secondary weed or weeds are not located. The presence of the primary and secondary weeds in the same or similar locations may be indicative of other (non-herbicide resistant) problems, such as poor or inconsistent herbicide application. The presence of the primary weed in locations where the secondary weed or weeds are not located may be indicative of herbicide resistance, since this may indicate that an herbicide is killing the secondary weeds but not the primary weed at those locations.

Essentially, these operations can involve identifying local clusters of a primary weed for the current growing season and one or more previous growing seasons. In some cases, these clusters may typically be roughly in patches (such as a pigweed natural distribution) or roughly in strips (such as a kochia natural distribution or via spreading in lines by equipment). Primary weed clusters that have persisted across two or more growing seasons can be identified, such as by determining whether any clusters of the primary weed during the current growing season overlap with or are near any clusters of the primary weed from one or more previous growing seasons. For a spreading weed, the current growing season's clusters can often be larger than last season's clusters. In order to rule out non-herbicide resistance causes of a weed cluster, the presence or absence of one or more secondary weeds can be used. For instance, all of the primary weed clusters can be checked for one or more secondary weeds. If, for example, the rate of secondary weed(s) in a primary weed cluster is found to be higher than the average rate of the secondary weed(s) in the same or other growing area, the presence of the primary weed in those clusters may actually be due to a problem in application or environment, rather than herbicide resistance.

If herbicide resistance is detected, an identification of one or more portions of the growing area(s) in which the primary weed has or may be developing herbicide resistance can be displayed at step 414. This may include, for example, the processing device 202 of the application server 106 displaying a graphical user interface on one or more of the user devices 102a-102d. The graphical user interface can highlight or otherwise identify the one or more portions of the growing area(s). As a particular example, the graphical user interface can provide a map or other graphical representation of a growing area with an alert indicating the location(s) of any patch(es) of suspected herbicide-resistant weeds. This may allow, for instance, farmers or other personnel to obtain one or more samples of the weeds from the suspected area(s) and perform traditional herbicide-resistant testing (such as assays or in a greenhouse) to confirm the presence of herbicide resistance. This may also or alternatively allow the farmers or other personnel to proceed with best management practices to contain and manage each patch of herbicide-resistant weeds. Depending on the urgency or farmer disposition, these actions may proceed in parallel with confirmation tests (aggressive practice) or after confirmation of herbicide resistance (looser practice). One or more other actions may be initiated at step 416. This may include, for example, the processing device 202 of the application server 106 automatically initiating one or more actions or initiating one or more actions after user acceptance. Example actions may include automated or other spraying of the identified portion(s) of the growing area(s) with a different herbicide, scheduling manual or other removal of all plants (including the weeds) in the identified portion(s) of the growing area(s), or automatically causing robotic machinery to avoid the identified portion(s) of the growing area(s).

In general, the described techniques allow for earlier detection of herbicide-resistant weeds, which is accomplished by analyzing spatial distributions (weed maps) of weeds in at least one growing area. These techniques support the automatic detection of herbicide-resistant weeds by using systematic data and systematic analyses, which enable identification of herbicide resistance problems in much smaller areas and much earlier in time than standard manual techniques. At the same time, these techniques can generate graphical user interfaces or other information that alerts one or more users (such as a farmer, agronomist, vendor, and/or other party or parties) that a certain patch in a growing area has an increased risk of herbicide resistance. As a result, these techniques can present results of analyses in a nontechnical manner that is familiar to users. This sort of presentation can improve the chances of acceptance, since it shows why a patch of a growing area has a higher risk of herbicide resistance. Some artificial intelligence/machine learning (AI/ML) products sometimes or often can be rejected if they make predictions and do not explain how those predictions are made. The described techniques can help to overcome these types of issues.

In some embodiments, these techniques may be used to detect the emergence of herbicide-resistant weeds in much smaller portions of a growing area. For example, these techniques may be used to detect the emergence of herbicide-resistant weeds while the weeds are below a 10-20% level in a field or other growing area. Detection from human observations often requires 20-30% prevalence of weeds in a growing area. This can correspond to significantly earlier detection, possibly on the order of several seasons (such as several years). Thus, this provides farmers, growers, and other parties with the ability to mitigate herbicide resistance problems before weeds become too widespread and overtake the field or other growing area.

Although FIG. 4 illustrates one example of a method 400 for detection of emerging herbicide resistance in weed populations, various changes may be made to FIG. 4. For example, while shown as a series of steps, various steps in FIG. 4 may overlap, occur in parallel, occur in a different order, or occur any number of times.

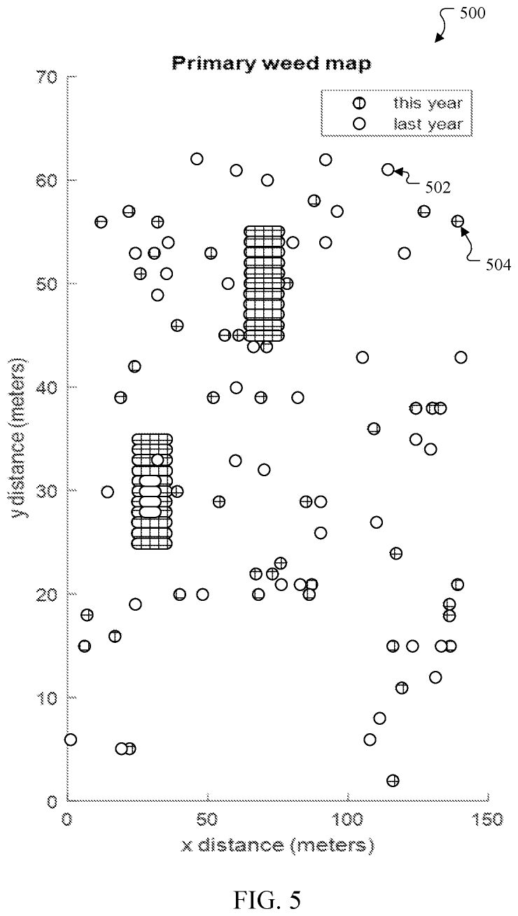

FIGS. 5 through 7 illustrate a first example detection of emerging herbicide resistance in weed populations according to this disclosure. For ease of explanation, the first example detection is described as resulting from use of the application server 106 in the system 100 of FIG. 1, which may implement the method 400 shown in FIG. 4. However, the application server 106 or method 400 may be used to generate any other suitable results depending on the specific circumstances.

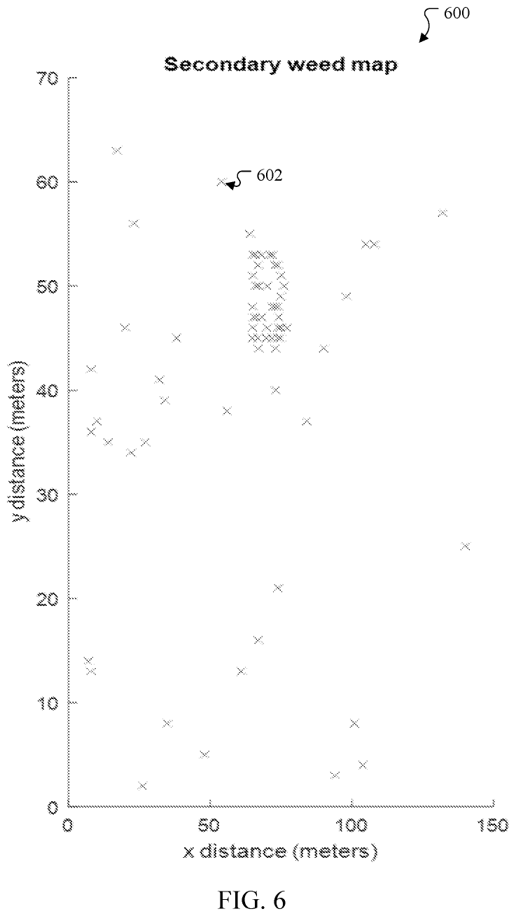

In this first example, FIG. 5 illustrates a primary weed map 500, where indicators 502 identify locations of a primary weed in a growing area during at least one previous growing season and indicators 504 identify locations of the primary weed in the growing area during a current growing season. FIG. 6 illustrates a secondary weed map 600, where indicators 602 identify locations of at least one secondary weed in the growing area during the current growing season.

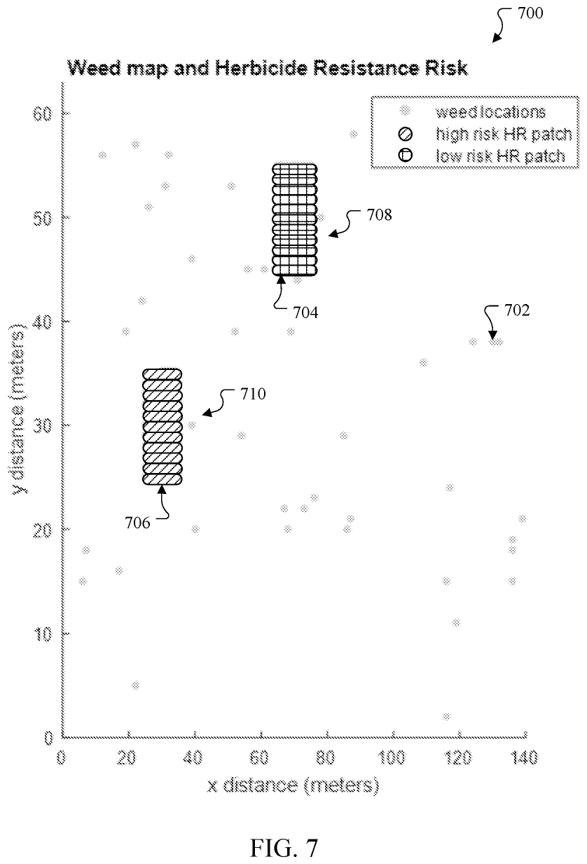

By processing these maps 500-600, the application server 106 can identify a risk map 700 as shown in FIG. 7. The risk map 700 includes indicators 702 that identify locations of the primary weed in the growing area. The risk map 700 also includes indicators 704 identifying locations associated with lower risks of herbicide resistance in the primary weed and indicators 706 identifying locations associated with higher risks of herbicide resistance in the primary weed. In this example, one cluster 708 of the primary weed has a lower risk of herbicide resistance since (i) that portion of the growing area contains the primary weed in the current growing season but not in the prior growing season and (ii) that portion of the growing area contains a large quantity of at least one secondary weed. In contrast, another cluster 710 of the primary weed has a higher risk of herbicide resistance since (i) that portion of the growing area contains the primary weed in the current growing season and in the prior growing season and has expanded and (ii) that portion of the growing area lacks a large quantity of the secondary weeds.

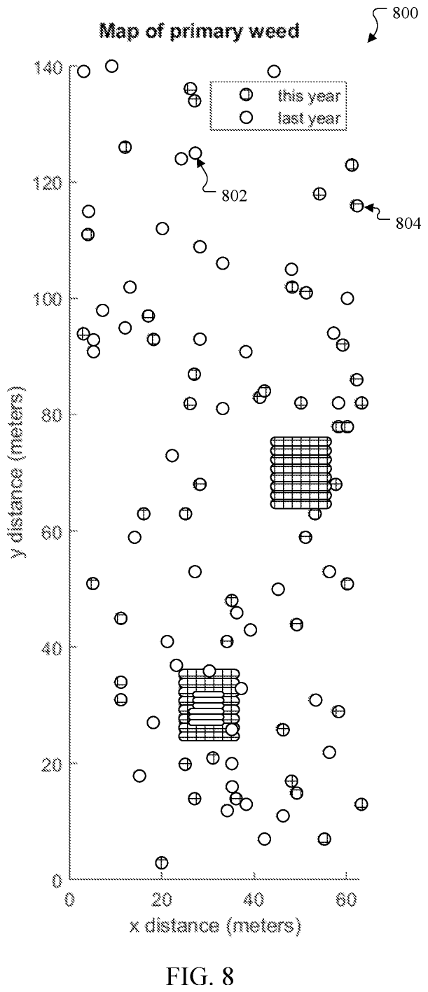

FIGS. 8 through 10 illustrate a second example detection of emerging herbicide resistance in weed populations according to this disclosure. For ease of explanation, the second example detection is described as resulting from use of the application server 106 in the system 100 of FIG. 1, which may implement the method 400 shown in FIG. 4. However, the application server 106 or method 400 may be used to generate any other suitable results depending on the specific circumstances.

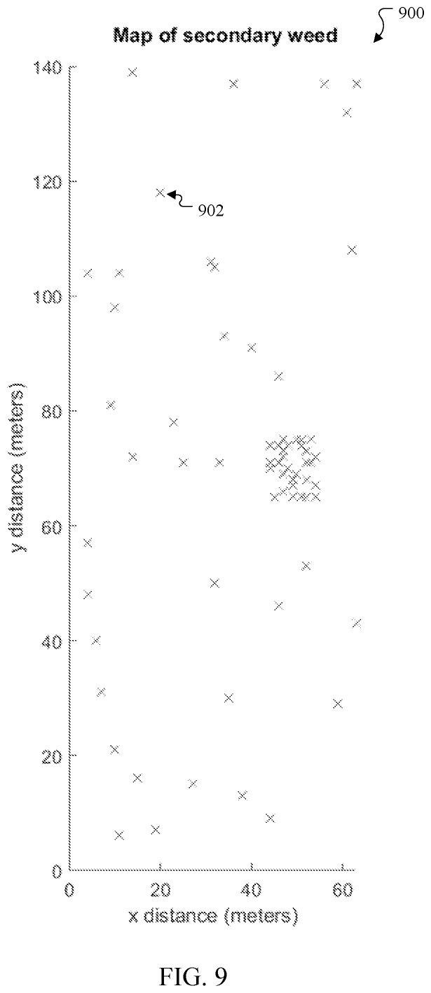

In this second example, FIG. 8 illustrates a primary weed map 800, where indicators 802 identify locations of a primary weed in a growing area during at least one previous growing season and indicators 804 identify locations of the primary weed in the growing area during a current growing season. FIG. 9 illustrates a secondary weed map 900, where indicators 902 identify locations of at least one secondary weed in the growing area during the current growing season.

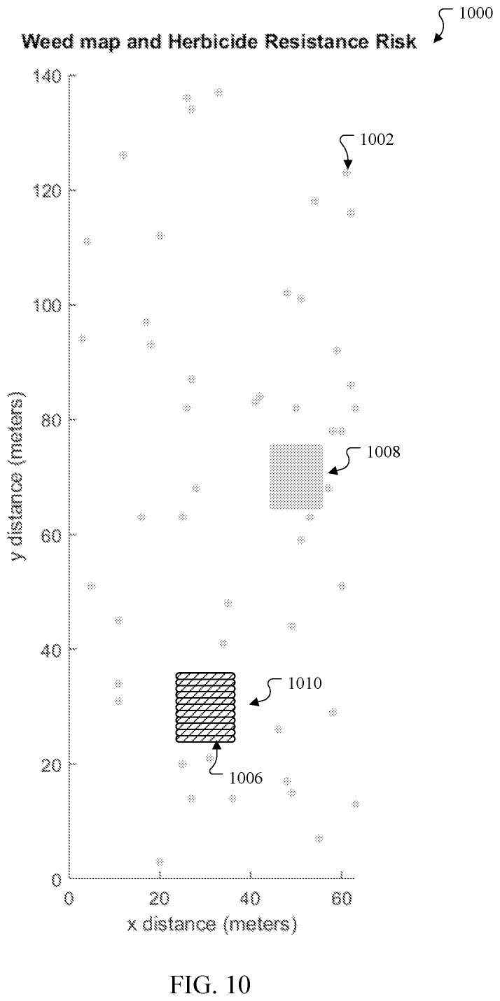

By processing these maps 800-900, the application server 106 can identify a risk map 1000 as shown in FIG. 10. The risk map 1000 includes indicators 1002 that identify locations of the primary weed in the growing area. The risk map 1000 also includes indicators 1006 identifying locations associated with higher risks of herbicide resistance in the primary weed. In this example, there are no indicators identifying locations associated with lower risks of herbicide resistance in the primary weed (although those could be included here). In this example, one cluster 1008 of the primary weed has no or very little risk of herbicide resistance since (i) that portion of the growing area contains the primary weed in the current growing season but not in the prior growing season and (ii) that portion of the growing area contains a large quantity of at least one secondary weed. In contrast, another cluster 1010 of the primary weed has a higher risk of herbicide resistance since (i) that portion of the growing area contains the primary weed in the current growing season and in the prior growing season and (ii) that portion of the growing area lacks a large quantity of the secondary weeds.

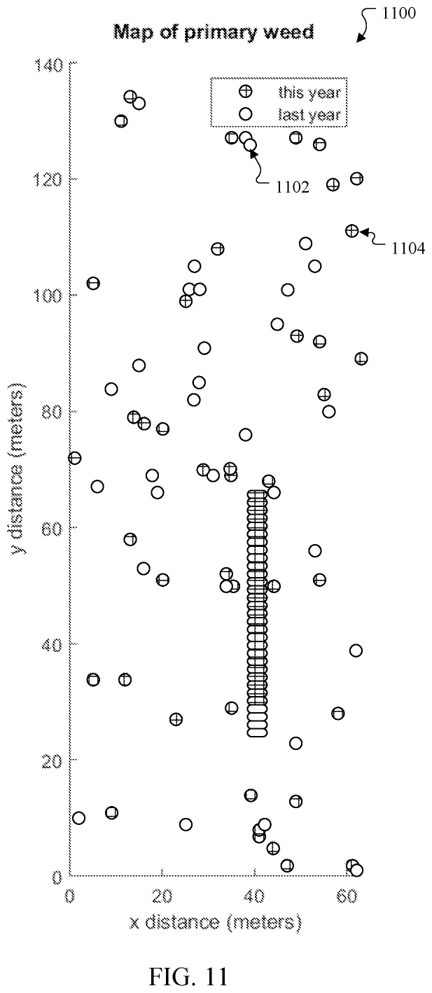

FIGS. 11 through 13 illustrate a third example detection of emerging herbicide resistance in weed populations according to this disclosure. For ease of explanation, the third example detection is described as resulting from use of the application server 106 in the system 100 of FIG. 1, which may implement the method 400 shown in FIG. 4. However, the application server 106 or method 400 may be used to generate any other suitable results depending on the specific circumstances.

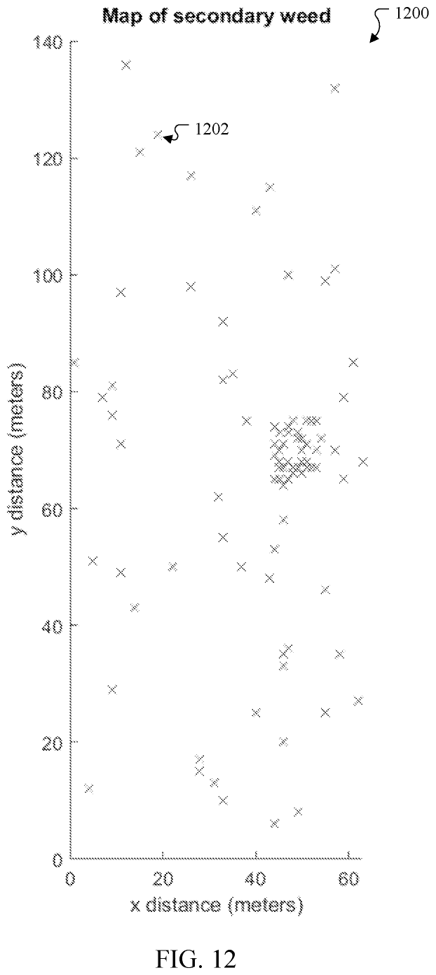

In this third example, FIG. 11 illustrates a primary weed map 1100, where indicators 1102 identify locations of a primary weed in a growing area during at least one previous growing season and indicators 1104 identify locations of a primary weed in the growing area during a current growing season. FIG. 12 illustrates a secondary weed map 1200, where indicators 1202 identify locations of at least one secondary weed in the growing area during the current growing season.

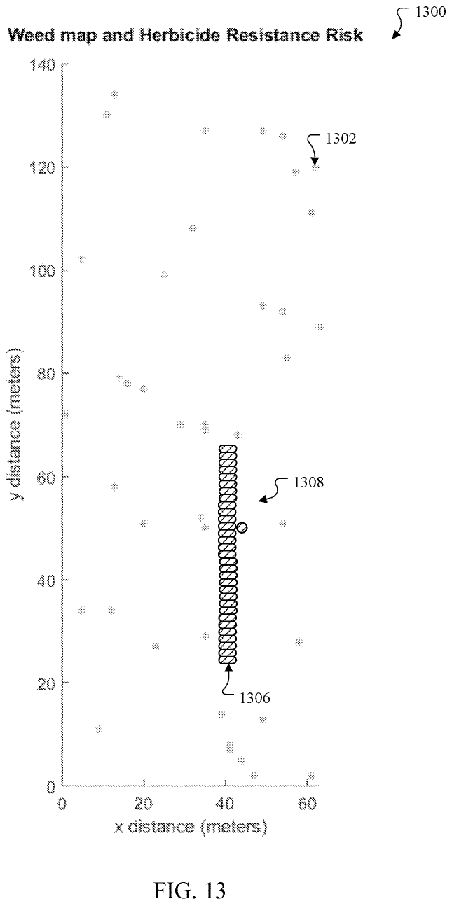

By processing these maps 1100-1200, the application server 106 can identify a risk map 1300 as shown in FIG. 13. The risk map 1300 includes indicators 1302 that identify locations of the primary weed in the growing area. The risk map 1300 also includes indicators 1306 identifying locations associated with higher risks of herbicide resistance in the primary weed. In this example, there are no indicators identifying locations associated with lower risks of herbicide resistance in the primary weed (although those could be included here). In this example, one cluster 1308 of the primary weed has a higher risk of herbicide resistance since (i) that portion of the growing area contains the primary weed in the current growing season and in the prior growing season and (ii) that portion of the growing area has an unusual (non-random) appearance. The unusual appearance here may be indicative of spatial dynamics of a weed that spread seeds via tumbleweeds, irrigation, farm equipment, or other mechanism.

Each of the risk maps 700, 1000, 1300 may be presented to one or more users, such as when shown as part of a graphical user interface. This may allow, for example, the one or more users to review information about the extend and possible spread of weeds and possibly initiate one or more actions associated with the detected weeds.

Although FIGS. 5 through 13 illustrate examples of detections of emerging herbicide resistance in weed populations, various changes may be made to FIGS. 5 through 13. For example, information about weeds and weed populations may be presented in any other suitable manner. Also, the indicators shown in these examples are for illustration only and can easily vary depending on the implementation.

Note that while the spatial information about at least a primary weed is often described above as being collected during multiple growing seasons, this need not be the case. For example, it is possible to collect spatial information after multiple spray events, which refer to events in which herbicide is sprayed onto at least portions of one or more growing areas. In some cases, for example, there may be four to ten spray events per growing season (although other numbers of spray events may occur). Thus, it is possible to collect spatial information during a single growing season and to use that spatial information when identifying potential or actual herbicide resistance. A combination of approaches can also be used, such as when spatial information is collected after multiple spray events during multiple growing seasons. In general, the spatial information simply needs to capture the presence of at least a primary weed over some span of time that can be indicative of potential or actual herbicide resistance.

It should be noted that the functions shown in or described with respect to FIGS. 1 through 13 can be implemented in a user device, server, or other device(s) in any suitable manner. For example, in some embodiments, at least some of the functions shown in or described with respect to FIGS. 1 through 13 can be implemented or supported using one or more software applications or other software instructions that are executed by the processing device 202 of a user device, server, or other device(s). In other embodiments, at least some of the functions shown in or described with respect to FIGS. 1 through 13 can be implemented or supported using dedicated hardware components. In general, the functions shown in or described with respect to FIGS. 1 through 13 can be performed using any suitable hardware or any suitable combination of hardware and software/firmware instructions. Moreover, the functions shown in or described with respect to FIGS. 1 through 13 can be performed using a single device or multiple devices.

In some cases, machine learning may be used to perform one or more of the functions shown in or described with respect to FIGS. 1 through 13. For example, a machine learning model may be trained and deployed for use in identifying clusters or patches of weeds that may be herbicide-resistant or that may be developing herbicide resistance. In some cases, the machine learning model may be trained by providing the machine learning model with training data (such as primary and secondary weed maps) and ground truths (such as known risk maps). Risk maps generated by the machine learning model using the training data can be compared to the ground truths, and differences (loss) between them can be measured. If the loss exceeds a threshold, weights or other parameters of the machine learning model can be adjusted, and the adjusted machine learning model can again be used to process training data so that additional risk maps can be generated and compared to the ground truths in order to measure additional losses. This can be repeated until the machine learning model is adequately trained to produce risk maps within a desired level of accuracy (as represented by the threshold). Note, however, that approaches other than those using machine learning may be used.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive (HDD), a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
obtaining, using at least one processing device of an electronic device, spatial information associated with weeds in a growing area, wherein the spatial information includes spatial information associated with a primary weed in the growing area over time;
identifying, using the at least one processing device, one or more portions of the growing area in which the primary weed has developed or may be developing herbicide resistance using the spatial information; and
outputting, using the at least one processing device, information associated with the one or more identified portions of the growing area.

2. The method of claim 1, wherein identifying the one or more portions of the growing area using the spatial information comprises:
determining that the primary weed is expanding in the one or more portions of the growing area over time.

3. The method of claim 2, wherein:
the spatial information also includes spatial information associated with one or more secondary weeds in the growing area; and
the method further comprises identifying one or more additional portions of the growing area in which the primary weed has not developed herbicide resistance using the spatial information.

4. The method of claim 3, wherein identifying the one or more portions of the growing area using the spatial information further comprises:
determining that the one or more secondary weeds are not present at a substantially higher rate in the one or more portions of the growing area compared to other portions of the growing area.

5. The method of claim 4, wherein identifying the one or more additional portions of the growing area using the spatial information comprises:
determining that the primary weed is expanding in the one or more additional portions of the growing area over time; and
determining that the one or more secondary weeds are present at the substantially higher rate in the one or more additional portions of the growing area compared to the other portions of the growing area.

6. The method of claim 1, further comprising:
identifying one or more spatial areas in the growing area, each spatial area associated with a common weed and identified using a clustering algorithm where points in the growing area are included in a common cluster based on their distance.

7. The method of claim 1, wherein outputting the information associated with the one or more identified portions of the growing area comprises:
generating a graphical user interface that identifies the one or more identified portions of the growing area.

8. The method of claim 1, wherein the spatial information comprises at least one of: measurements from a tractor sprayer-based sensor, drone-based observations, and satellite observations of weed locations.

9. The method of claim 1, further comprising:
identifying one or more spatial areas in the growing area, each spatial area associated with a common weed and identified using an anomaly detection algorithm where points in the growing area are identified as an anomaly based on their growth rate.

10. The method of claim 1, wherein identifying the one or more portions of the growing area using the spatial information comprises:
determining that the primary weed has exhibited a different growth rate than an average growth rate of weeds in the growing area.

11. An apparatus comprising:
at least one processing device configured to:
obtain spatial information associated with weeds in a growing area, wherein the spatial information includes spatial information associated with a primary weed in the growing area over time;
identify one or more portions of the growing area in which the primary weed has developed or may be developing herbicide resistance using the spatial information; and
output information associated with the one or more identified portions of the growing area.

12. The apparatus of claim 11, wherein, to identify the one or more portions of the growing area using the spatial information, the at least one processing device is configured to determine that the primary weed is expanding in the one or more portions of the growing area over time.

13. The apparatus of claim 12, wherein:
the spatial information also includes spatial information associated with one or more secondary weeds in the growing area; and
the at least one processing device is further configured to identify one or more additional portions of the growing area in which the primary weed has not developed herbicide resistance using the spatial information.

14. The apparatus of claim 13, wherein, to identify the one or more portions of the growing area using the spatial information, the at least one processing device is further configured to determine that the one or more secondary weeds are not present at a substantially higher rate in the one or more portions of the growing area compared to other portions of the growing area.

15. The apparatus of claim 14, wherein, to identify the one or more additional portions of the growing area using the spatial information, the at least one processing device is configured to:
determine that the primary weed is expanding in the one or more additional portions of the growing area over time; and
determine that the one or more secondary weeds are present at the substantially higher rate in the one or more additional portions of the growing area compared to the other portions of the growing area.

16. The apparatus of claim 11, wherein the at least one processing device is further configured to identify one or more spatial areas in the growing area, each spatial area associated with a common weed and identified using a clustering algorithm where points in the growing area are included in a common cluster based on their distance.

17. The apparatus of claim 11, wherein, to output the information associated with the one or more identified portions of the growing area, the at least one processing device is configured to generate a graphical user interface that identifies the one or more identified portions of the growing area.

18. The apparatus of claim 11, wherein the spatial information comprises at least one of: measurements from a tractor sprayer-based sensor, drone-based observations, and satellite observations of weed locations.

19. The apparatus of claim 11, wherein the at least one processing device is further configured to identify one or more spatial areas in the growing area, each spatial area associated with a common weed and identified using an anomaly detection algorithm where points in the growing area are identified as an anomaly based on their growth rate.

20. The apparatus of claim 11, wherein, to identify the one or more portions of the growing area using the spatial information, the at least one processing device is configured to determine that the primary weed has exhibited a different growth rate than an average growth rate of weeds in the growing area.

21. A non-transitory computer readable medium storing computer readable program code that, when executed by one or more processors, causes the one or more processors to:
obtain spatial information associated with weeds in a growing area, wherein the spatial information includes spatial information associated with a primary weed in the growing area over time;
identify one or more portions of the growing area in which the primary weed has developed or may be developing herbicide resistance using the spatial information; and
output information associated with the one or more identified portions of the growing area.

22. The non-transitory computer readable medium of claim 21, wherein the computer readable program code that when executed causes the one or more processors to identify the one or more portions of the growing area using the spatial information comprises:
computer readable program code that when executed causes the one or more processors to determine that the primary weed is expanding in the one or more portions of the growing area over time.

23. The non-transitory computer readable medium of claim 22, wherein:
the spatial information also includes spatial information associated with one or more secondary weeds in the growing area; and
the non-transitory computer readable medium also stores computer readable program code that when executed causes the one or more processors to identify one or more additional portions of the growing area in which the primary weed has not developed herbicide resistance using the spatial information.

24. The non-transitory computer readable medium of claim 23, wherein the computer readable program code that when executed causes the one or more processors to identify the one or more portions of the growing area using the spatial information further comprises:
computer readable program code that when executed causes the one or more processors to determine that the one or more secondary weeds are not present at a substantially higher rate in the one or more portions of the growing area compared to other portions of the growing area.

25. The non-transitory computer readable medium of claim 24, wherein the computer readable program code that when executed causes the one or more processors to identify the one or more additional portions of the growing area using the spatial information comprises:
computer readable program code that when executed causes the one or more processors to determine that the primary weed is expanding in the one or more additional portions of the growing area over time; and
computer readable program code that when executed causes the one or more processors to determine that the one or more secondary weeds are present at the substantially higher rate in the one or more additional portions of the growing area compared to the other portions of the growing area.

26. The non-transitory computer readable medium of claim 21, further storing computer readable program code that when executed causes the one or more processors to identify one or more spatial areas in the growing area, each spatial area associated with a common weed and identified using a clustering algorithm where points in the growing area are included in a common cluster based on their distance.

27. The non-transitory computer readable medium of claim 21, wherein the computer readable program code that when executed causes the one or more processors to output the information associated with the one or more identified portions of the growing area comprises:
computer readable program code that when executed causes the one or more processors to generate a graphical user interface that identifies the one or more identified portions of the growing area.

28. The non-transitory computer readable medium of claim 11, wherein the spatial information comprises at least one of: measurements from a tractor sprayer-based sensor, drone-based observations, and satellite observations of weed locations.

29. The non-transitory computer readable medium of claim 11, further storing computer readable program code that when executed causes the one or more processors to identify one or more spatial areas in the growing area, each spatial area associated with a common weed and identified using an anomaly detection algorithm where points in the growing area are identified as an anomaly based on their growth rate.

30. The non-transitory computer readable medium of claim 11, wherein the computer readable program code that when executed causes the one or more processors to identify the one or more portions of the growing area using the spatial information comprises:
computer readable program code that when executed causes the one or more processors to determine that the primary weed has exhibited a different growth rate than an average growth rate of weeds in the growing area.
